(19) United States
(12) Patent Application Publication
(10) Pub. No.: US 2009/0236676 A1
(43) Pub. Date: Sep. 24, 2009

(54) STRUCTURE AND METHOD TO MAKE HIGH PERFORMANCE MOSFET WITH FULLY SILICIDED GATE

(75) Inventors: Huilong Zhu, Poughkeepsie, NY (US); Daewon Yang, Hopewell Junction, NY (US); Yanfeng Wang, Fishkill, NY (US); Brian J. Greene, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 12/052,069

(22) Filed: Mar. 20, 2008

(51) Int. Cl. H01L 29/78; H01L 21/44

(52) U.S. Cl. 257/413; 438/683; 257/E29.255; 257/E21.296

(57) ABSTRACT

The present invention in one embodiment provides a method of producing a device including providing a semiconducting device including a gate structure including a silicon containing gate conductor atop a substrate; forming a metal layer on at least the silicon containing gate conductor; and directing chemically inert ions to impact the metal layer, wherein momentum transfer from of the chemically inert ions force metal atoms from the metal layer into the silicon containing gate conductor to provide a silicide gate conductor.

### FIELD OF THE INVENTION

The present invention generally relates to microelectronics. In one embodiment, the present invention relates to metal silicide gate structures in metal oxide semiconductor field effect transistors (MOSFETs).

### BACKGROUND OF THE INVENTION

As technology progresses and higher switching speeds are sought, the physical size of semiconductor devices continues to decrease. Early MOS devices often had metal gate electrodes made from aluminum or alloys of aluminum. Aluminum was preferred for its ease of deposition and etching, its favorable adhesion to SiO₂ and Si surfaces, and its lack of corrosion issues. However, aluminum had some downsides, such as electromigration and spiking into shallow junctions. Further, as multiple levels of metal interconnects at the back-end-of-the-line, aluminum and aluminum alloys were not able to withstand the high thermal budgets needed for deposition and annealing of intermetal dielectrics due to aluminum's low melting and alloying temperatures.

Doped polysilicon gate electrodes lead to complementary-MOS (CMOS) technology that provided the ability to tailor the work function of the gate electrode for negative-channel MOS (NMOS) and positive-channel MOS (PMOS) devices. Scaling down the physical size of semiconductor devices has continued due to technical and economic factors. Transistor physical gate length (or channel length) is reaching a point where doping levels in polysilicon can no longer be increased sufficiently to support the electrical potential profiles desired.

In CMOS devices where the polysilicon gate electrode is doped with an opposite conductivity type than the channel in the substrate, there is a tendency for the gate electrode to deplete and invert when the device is biased into substrate inversion for operation. Any depletion of the polysilicon surface at the gate dielectric acts as an additional dielectric region, which increases the equivalent oxide thickness (EOT) of the gate dielectric. This alters the threshold voltage in an uncontrollable and undesirable way. As a result, there has been a return to the use of metal gate electrodes in the form of metal silicided gate electrodes.

### SUMMARY OF THE INVENTION

In one embodiment, the present invention provides a method of forming a silicided gate structure. In one embodiment, the method includes:

providing a semiconducting device comprising a gate structure including a silicon containing gate conductor atop a substrate;
forming a metal layer on at least the silicon containing gate conductor; and
directing chemically inert ions to impact the metal layer, wherein the chemically inert ions force metal atoms via momentum transfer from the metal layer into the silicon containing gate conductor to provide a silicide gate conductor.

In one embodiment, the step of directing the chemically inert ions at the metal layer includes sputtering. In one embodiment, the chemically inert ions include Ar⁺ N, Xe and Kr). In one embodiment, the chemically inert ions have an ion energy ranging from about 5 eV to about 200 eV. In one embodiment, the step of sputtering further includes a temperature ranging from about 400° C. to about 600° C., the chemically inert ions comprise Ar, N, or combinations thereof, and the chemically inert ions are directed to impact the metal layer with a ion energy ranging from about 5 eV to about 200 eV.

In one embodiment, the metal layer is composed of Ni, Co, Ti, Pt, Ta, W or multilayers and alloys thereof. In one embodiment, the present invention further includes forming a metal nitride layer atop the metal layer prior to the step of directing the chemically inert ions to impact the metal layer. In one embodiment, the metal nitride is composed of TiN, TaN, W, or multilayers and alloys thereof. In one embodiment, the silicide gate conductor is a fully silicided gate conductor.

In another embodiment of the present invention, a gate region including a silicided gate conductor is provided by a method that includes the steps of:

providing a semiconducting device comprising a gate structure including a silicon containing gate conductor atop a substrate;
forming a silicide on at least an upper portion of the silicon containing gate conductor; and
directing chemically inert ions to impact the silicide at the upper portion of the silicon containing gate, wherein the chemically inert ions force metal atoms via momentum transfer from the silicide to a lower portion of the silicon containing gate conductor to provide a fully silicided gate conductor.

In one embodiment, forming a metal silicide on at least the upper portion of the silicon containing gate conductor includes depositing a metal atop the silicon containing gate conductor, and annealing to form a silicide. In one embodiment, the upper portion of the silicon containing gate conductor that is consumed during silicidation extends to a depth that is half the thickness or less than the silicon containing gate conductor. In one embodiment, the metal deposited atop the silicon containing gate conductor is selected from the group including, but not limited to: Ni, Ti, Co, Mo, Pt, Ta, or W. In one embodiment, the silicide that is formed on the upper portion of the silicon containing gate conductor is composed of NiSi₂, TiSi₂, CoSi₂, MoSi₂, PtSi₂, TaSi₂, WSi, or combinations thereof.

In one embodiment, prior to the directing the chemically inert ions to impact the silicide, the method further includes forming a first dielectric layer on at least the silicide on the upper portion of the silicon containing gate conductor; forming second dielectric regions adjacent the gate structure, wherein an upper surface of the second dielectric regions is coplanar with an upper surface of the first dielectric layer on the silicide that is positioned in an upper portion of the silicon containing gate conductor; and removing the first dielectric layer from the silicide.

In one embodiment, the step of forming the first dielectric layer on at least the silicide comprises depositing a nitride. In one embodiment, the step of forming the second dielectric regions comprises depositing an oxide atop the substrate and the gate structure, and then planarizing the oxide until the upper surface of the first dielectric layer is exposed.

In one embodiment, the step of removing the first dielectric layer includes an anisotropic etch step including an etch chemistry for removing the first dielectric layer selective to the second dielectric regions.

In one embodiment, the step of directing the chemically inert ions to the silicide includes sputtering of Ar⁺ or N⁺. In one embodiment, the chemically inert ions have an ion energy ranging from about 5 eV to about 200 eV.

In another aspect of the present invention, a semiconducting device is provided that includes a fully silicided gate. In one embodiment, the semiconducting device includes:

a substrate including a channel positioned between a source and a drain region; and
a gate structure including a gate stack and a facetted spacer abutting the gate stack, the gate structure comprising a gate dielectric positioned atop the channel of the substrate, and a fully silicided gate conductor atop the gate dielectric, wherein the facetted spacer has an angle at an intersection of a planar upper face of the facetted spacer and a sidewall of the facetted spacer abutting the gate conductor is less than about 75 degrees.

### BRIEF DESCRIPTION OF THE DRAWINGS

The following detailed description, given by way of example and not intended to limit the invention solely thereto, will best be appreciated in conjunction with the accompanying drawings, wherein like reference numerals denote like elements and parts, in which:

FIG. 1 is a side cross sectional view of an initial structure including a gate structure including a silicon containing gate conductor atop a semiconducting substrate, as used in accordance with at least one embodiment of the present invention.

FIG. 2 is a side cross sectional view depicting depositing at least one metal layer atop the structure depicted in FIG. 1, in accordance with one embodiment of the present invention.

FIG. 3 is a side cross sectional view depicting directing chemically inert ions to impact the at least one metal layer, wherein momentum transfer from the chemically inert ions force metal atoms from the at least one metal layer into the silicon containing gate conductor to provide a silicide gate conductor, in accordance with at least one embodiment of the present invention.

FIG. 4 is a side cross sectional view depicting one embodiment of clean process applied to the structure depicted in FIG. 3, in accordance with the present invention.

FIG. 5 is a side cross sectional view depicting an initial structure of another embodiment of the present invention including a semiconducting device comprising a gate structure including a silicon containing gate conductor atop a substrate; and a silicide on at least the upper portion of the silicon containing gate conductor, as used in accordance with the present invention.

FIG. 6 is a side cross sectional view depicting forming a first dielectric layer on at least the silicide that is positioned on the upper portion of the silicon containing gate conductor; and forming second dielectric regions adjacent the gate structure, wherein an upper surface of the second dielectric regions is coplanar with an upper surface of the first dielectric layer on the silicide that is positioned in an upper portion of the silicon containing gate conductor, in accordance with the present invention.

FIG. 7 is a side cross sectional view depicting removing the first dielectric layer from the silicide and directing chemically inert ions to impact the silicide at the upper portion of the silicon containing gate, wherein momentum transfer from the chemically inert ions forces metal atoms from the silicide to a lower portion of the silicon containing gate conductor to provide a fully silicided gate conductor, in accordance with at least one embodiment of the present invention.

### DETAILED DESCRIPTION OF THE INVENTION

The embodiments of the present invention relate to novel methods for forming semiconducting devices. When describing the methods, the following terms have the following meanings, unless otherwise indicated. The present invention, which in one embodiment provides a method for forming fully silicided gate structures, will now be described in greater detail by referring to the following discussion and drawings that accompany the present application. It is noted that the drawings of the present application are provided for illustrative purposes only and, as such, the drawings are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

When describing the methods and structures of the present invention, the following terms have the following meanings, unless otherwise indicated.

As used herein, “semiconductor device” refers to an intrinsic semiconductor material that has been doped, that is, into which a doping agent has been introduced, giving it different electrical properties than the intrinsic semiconductor. Doping involves adding dopant atoms to an intrinsic semiconductor, which changes the electron and hole carrier concentrations of the intrinsic semiconductor at thermal equilibrium. Dominant carrier concentrations in an extrinsic semiconductor classify it as either an n-type or p-type semiconductor. In intrinsic semiconductors the valence band and the conduction band are separated by the energy gap that is less than about 3.5 eV.

As used herein, a “P-type semiconductor” refers to the addition of trivalent impurities to an intrinsic semiconductor substrate that creates deficiencies of valence electrons, such as boron, aluminum or gallium to an intrinsic Si-containing substrate.

As used herein, an “N-type semiconductor” refers to the addition of pentavalent impurities that contributes free electrons to an intrinsic semiconductor substrate, such as antimony, arsenic or phosphorous impurities to an intrinsic Si-containing substrate.

A “gate structure” means a structure used to control output current (i.e. flow of carriers in the channel) of a semiconducting device, such as a field effect transistor (FET).

As used herein, a “metal” is an electrically conductive material, wherein in metals the atoms are held together by the force of metallic bond; and the energy band structure of the metal's conduction and valence bands overlap, and hence, there is no energy gap.

A “silicide” is an alloy of a metal and a semiconductor.

The term “fully silicided gate” denotes that substantially the entire gate conductor extending from the gate conductors upper surface to the interface of the gate conductor and the gate dielectric is composed of silicide.

The term “momentum transfer” means that momentum is transferred to host atoms from high energy particles during plasmas bombardment or implantation.

As used herein, the term “dielectric” denote a non-metallic material having insulating properties.

As used herein, “insulating” denotes a room temperature conductivity of less than about 10⁻¹⁰(Ω-m)⁻¹.

As used herein, the term “chemically inert” denotes that the atoms that impact the metal layer, metal nitride layer or combinations thereof do not undergo substantial chemical reaction upon impact.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the invention, as it is oriented in the drawing figures.

Further, it will be understood that when an element as a layer, region or substrate is referred to as being “atop” or “over” or “overlying” or “below” or “underlying” another element, it can be directly on the other element or intervening elements may also be present. In contrast, when an element is referred to as being “on”, “directly on” or “directly over” of in “direct physical contact” with another element, there are no intervening elements present.

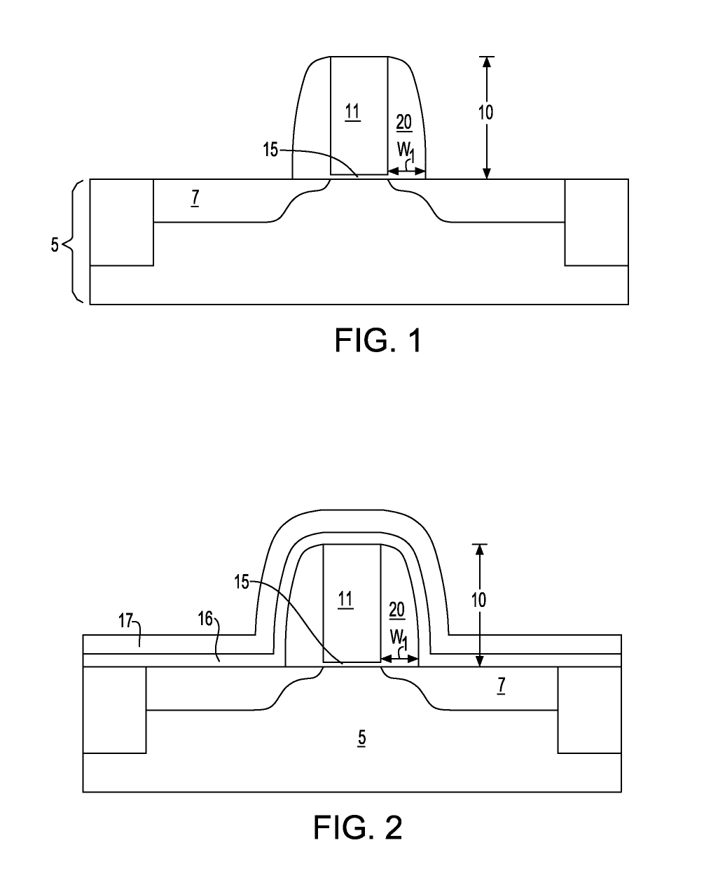

FIGS. 1 to 4 depict one embodiment of the present method for forming a semiconducting device, such as a metal oxide semiconducting field effect transistor (MOSFET), including a fully silicided gate conductor. FIG. 1 depicts an initial structure for one embodiment of the present method, in which the initial structure may include a substrate 5 including source and drain regions 7 separated by a channel, and a gate structure 10 substantially overlying the channel of the substrate 5, wherein the gate structure 10 includes a silicon containing gate conductor 11, a gate dielectric 15 and at least one dielectric spacer 20.

In one embodiment, the substrate 5 includes, but is not limited to: Si-containing materials, GaAs, InAs and other like semiconductors. Si-containing materials as used to provide the substrate 5 include, but are not limited to: Si, bulk Si, single crystal Si, polycrystalline Si, SiGe, amorphous Si, silicon-on-insulator substrates (SOI), SiGe-on-insulator (SGOI), strained-silicon-on-insulator, annealed poly Si, and poly Si line structures. In one embodiment in which the substrate 5 is a silicon-on-insulator (SOI) or SiGe-on-insulator (SGOI) substrate, the thickness of the Si-containing layer atop the buried insulating layer can have a thickness on the order of 10 nm or greater. In one embodiment, the SOI or SGOI substrate may be fabricated using a thermal bonding process, or in another embodiment may be fabricated by an ion implantation process.

Still referring to FIG. 1, the gate structure 10 may be formed atop the substrate 5 utilizing deposition and lithography processes. More specifically, in one embodiment, a gate structure 10 is provided atop the substrate 5 by depositing a gate dielectric layer followed by a gate conductor layer. In a following process step, the gate stack is patterned using photolithography and etch processes. For example, following the deposition of the gate dielectric layer and the gate conductor layer, an etch mask is formed atop the gate conductor layer protecting the portion of the layered stack that provides the gate stack, wherein the portions exposed by the etch mask are removed by an anisotropic etch process, such as a reactive ion etch. Reactive ion etch is a form of plasma etching, in which the surface to be etched is placed on the RF powered electrode and takes on a potential that accelerates an etching species, which is extracted from a plasma, towards the surface to be etched, wherein a chemical etching reaction takes place in the direction normal to the surface being etched. In one embodiment, the etch mask may be provided by a patterned photoresist layer. In one embodiment, the structure depicted in FIG. 1 may be provided by a replacement gate process.

In one embodiment, the gate dielectric 15 of the gate stack is composed of an oxide material. Suitable examples of oxides that can be employed as the gate dielectric 15 include, but are not limited to: SiO₂, Al₂O₃, ZrO₂, HfO₂, Ta₂O₃, TiO₂, perovskite-type oxides and combinations and multi-layers thereof. In a further embodiment, the gate dielectric 15 may also be composed of a nitride, oxynitride, or a combination (or multi layer) of oxide, nitride and oxynitride. In one embodiment, the gate dielectric 15 has a thickness greater than approximately 0.8 nm. In another embodiment, the gate dielectric 15 has a thickness ranging from about 1.0 nm to about 6.0 nm. In one embodiment, the gate dielectric 15 is formed using chemical vapor deposition (CVD) including, but not limited to: atomic layer CVD (ALCVD), pulsed CVD, plasma assisted CVD. In another embodiment, the gate dielectric 15 is formed by a thermal growing process, which may include oxidation, oxynitridation, nitridation, and/or plasma or radical treatment. In one embodiment, the gate dielectric 15 may be a high-k gate dielectric comprised of an insulating material having a dielectric constant of greater than about 3.9. In another embodiment, the gate dielectric 15 is a high-k gate dielectric comprised of an insulating material having a dielectric constant greater than 7.0. In one embodiment, a high-k gate dielectric is provided by HfO₂, hafnium silicate, hafnium silicon oxynitride or combinations thereof.

In one embodiment, the gate conductor 11 of the gate structure 10 is composed of a silicon containing material, which may be polysilicon. In another embodiment, the gate conductor 11 is composed of single crystal Si, SiGe, SiGeC or combinations thereof. In one embodiment, the gate conductor 11 is formed atop the gate dielectric 15 utilizing a deposition process, such as CVD and physical vapor deposition (PVD). In one embodiment, the gate conductor 11 is composed of a doped silicon containing material. The dopant can be elements from group III-A or group V of the Periodic Table of Elements. The dopant may be introduced during deposition of the gate conductor layer or following subsequent patterning and etching of the gate conductor 11. In one embodiment, the gate conductor 11 has a height ranging from about 20 nm to about 50 nm. In another embodiment, the gate conductor 11 has a height ranging from about 20 nm to about 40 nm. In a further embodiment, the gate conductor 11 has a height ranging from about 25 nm to about 35 nm.

Still referring to FIG. 1, following the formation of the gate stack, at least one dielectric spacer 20, also referred to as a sidewall spacer, is formed abutting the gate stack sidewalls. In one embodiment, the at least one dielectric spacer 20 is a nitride, such as silicon nitride (Si₃N₄). In another embodiment, the at least one dielectric spacer 20 may be composed of an oxide. The sidewall spacer width W1 may range from about 10 nm to about 60 nm. In one embodiment, the at least one dielectric spacer 20 may be provided by forming processes, such as deposition or thermal growth. In one embodiment, the at least one dielectric spacer 20 are formed by deposition processes, such as chemical vapor deposition (CVD) in combination with an anisotropic etch, such as reactive ion etch.

In a following process step, source and drain regions 7 are formed in substrate 5 corresponding to the sidewalls of the gate stack. In one embodiment, source and drain regions 7 are formed via ion implantation and comprise a combination of normally incident and angled implants to form the desired grading. In one embodiment, PFET devices are produced within Si-containing substrates by doping the source and drain regions 7 with elements from group III of the Periodic Table of Elements. In another embodiment, NFET devices are produced within Si-containing substrates by doping the source and drain regions 7 with elements from group V-A of the Periodic Table of Elements. It is noted that the substrate 5 may further include extension dopant regions and halo dopant regions, as well as additional spacers utilized in forming extension dopant regions. Although not depicted in the Figures, these regions are within the scope of the present invention.

FIG. 2 depicts one embodiment of depositing a metal layer 16 and a metal nitride layer 17 atop the structure depicted in FIG. 1. In one embodiment, the metal nitride layer 17, e.g., TiN, acts as an oxygen barrier layer. Specifically, in one embodiment, the metal layer 16 is formed atop the gate structure 10 including the gate conductor 11, the at least one dielectric spacer 20, as well as the exposed surface of the substrate 5 that are adjacent to the gate structure 10. In a following processing step, the metal nitride layer 17 is deposited atop the metal layer 16.

In one embodiment, the metal layer 16 may be composed of Ni, Co, Ti, Pt or combinations and alloys thereof, as well as multilayers thereof. In one embodiment, the metal layer 16 may have a thickness ranging from about 5 nm to about 20 nm. In another embodiment, the metal layer 16 may have a thickness ranging from about 8 nm to about 15 nm.

In one embodiment, the metal layer 16 may be deposited by physical vapor deposition. In one embodiment, physical vapor deposition (PVD) can include plating, sputter deposition, molecular beam epitaxial deposition, or electron beam deposition. In another embodiment, the metal layer 16 may be deposited by chemical vapor deposition (CVD). Chemical vapor deposition is a deposition process in which a deposited species is formed as a result of a chemical reaction between gaseous reactants at greater than room temperature, wherein solid product of the reaction is deposited on the surface on which a film, coating, or layer of the solid product is to be formed. Variations of CVD processes include, but are not limited to: Atmospheric Pressure CVD (APCVD), Low Pressure CVD (LPCVD), Plasma Enhanced CVD (EPCVD), Metal-Organic CVD (MOCVD) and combinations thereof. In one embodiment, the metal layer 16 may be deposited using a conformal deposition method. The term “conformal” denotes a layer having a thickness that does not deviate from greater than or less than 20% of an average value for the thickness of the layer.

In a following process step, the metal nitride layer 17 is formed atop the metal layer 16. The metal nitride layer 17 may be composed of TiN, TaN, WN, or combinations and alloys thereof. In one embodiment, the metal nitride layer 17 may have a thickness ranging from about 3 nm to about 15 nm. In another embodiment, the metal nitride layer 17 may have a thickness ranging from about 4 nm to about 7 nm. In one embodiment, the deposition method of metal nitride layer includes chemical vapor deposition (CVD). In one embodiment, the metal nitride layer 17 is deposited by physical vapor deposition (PVD), which may include but is not limited to: plating, sputter deposition, molecular beam epitaxial deposition, electron beam deposition and combinations thereof. In another embodiment, the metal nitride layer 17 is deposited by chemical vapor deposition (CVD), which may include, but is not limited to: Atmospheric Pressure CVD (APCVD), Low Pressure CVD (LPCVD), Plasma Enhanced CVD (EPCVD), Metal-Organic CVD (MOCVD) and combinations thereof. In one embodiment, the metal nitride layer 17 may be deposited using a conformal deposition method. In one embodiment, the deposition method for forming the metal nitride layer 17 may include atomic layer deposition (ALD) or pulse CVD. In one embodiment when the metal nitride layer 17 is deposited by pulsed CVD (ALD), nitrogen and metal precursors are pulsed one after each other with optional neutral gas added in between the pulsing steps.

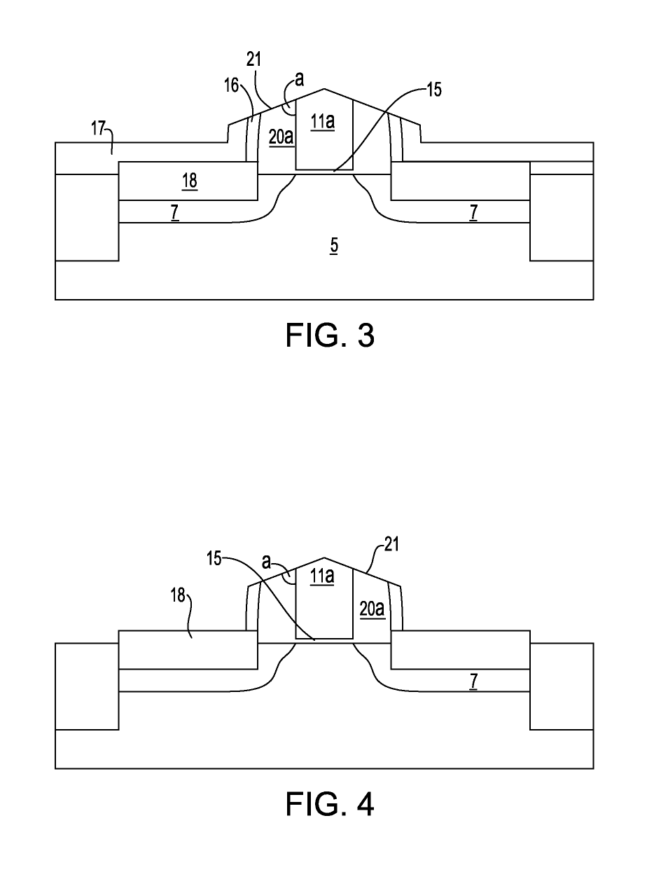

FIG. 3 depicts one embodiment of directing chemically inert ions to impact the metal layer 16, wherein momentum transfer from the chemically inert ions forces metal atoms from the metal layer 16 into the silicon containing gate conductor to provide a metal silicide gate conductor 11a. In one embodiment, the chemically inert ions include Ar⁺ or N⁺ or Kr⁺.

In one embodiment, the directing chemically inert ions is provided by ion milling, which may also be referred to as sputtering. In one embodiment, ion milling includes positioning the substrate 5 containing the gate structure 10 in a vacuum chamber, wherein a stream of argon is introduced into the chamber. Upon entering the chamber, the argon is subjected to a stream of high-energy electrons from a set of anode and cathode electrodes. The electrons ionize the argon atoms to a high-energy state with a positive charge. The substrate 5 is held on a negatively grounded holder, which attracts the ionized argon atoms. As the argon atoms travel to the gate structure 10 they accelerate picking up momentum.

In one embodiment, the chemically inert ions have an ion energy ranging from about 5 eV to about 200 eV. In another embodiment, the chemically inert ions have an ion energy ranging from about 10 eV to about 50 eV. In an even further embodiment, the chemically inert ions have an ion energy ranging from about 10 eV to about 30 eV.

In one embodiment, the directing of the chemically inert ions includes ion milling at a temperature ranging from about 300° C. to about 600° C. In another embodiment, the directing of the chemically inert ions includes ion milling at a temperature ranging from about 350° C. to about 550° C. In an even further embodiment, the directing of the chemically inert ions includes ion milling at a temperature ranging from about 350° C. to about 500° C.

In one embodiment, directing the chemically inert atoms to contact the gate structure 10, removes a portion of the metal nitride layer 17 a portion of the dielectric spacers 20, and a portion of the gate conductor 11a. In one embodiment, the chemically inert atoms contact the upper surface of the metal nitride layer 17, the gate conductor 11 and the at least one dielectric spacer 20 removing material by momentum transfer, as well as impacting portions of the metal layer 16, wherein the chemically inert atoms chemically inert ions force metal atoms from the metal layer 16 to a portion of the silicon containing gate conductor to provide a silicided gate conductor 11a. In one embodiment, a fully silicided gate conductor is provided 11a.

In one embodiment, the angle of incidence of chemically inert atoms impinging on the upper surface of the at least one dielectric spacer 20 is selected to provide an etched spacer 20a having a facetted upper surface 21, which is hereafter referred to as a facetted spacer 20a. In one embodiment, the facetted upper surface 21 is a planar surface, wherein the facet angle α at the intersection of the planar surface 21 to the sidewall 22 of the facetted spacer 20a that is abutting the gate stack 11 is at an acute angle. In one embodiment, the facet angle α is less than 75°. In another embodiment, the facet angle α ranges from about 20 degrees to about 60 degrees. In a further embodiment, the facet angle α ranges from about 25 degrees to about 45 degrees. In one embodiment, the facet angle α is less than 30°.

In one embodiment, during the formation of the silicided gate conductor 11a, silicide contacts 18 form on an upper surface of the source and drain regions 7 of the substrate 5. More specifically, in one embodiment, the metal of the metal layer 16 reacts with the substrate 5 to provide a metal silicide contact 18 to the source and drain regions 7. In one embodiment when the metal layer 16 is composed of Ni and the substrate 5 contains Si, a nickel silicide (NiSi) contact 18 forms atop the source and drain regions 7 of the substrate 5. In another embodiment when the metal layer 16 is composed of Co and the substrate 5 contains Si, a cobalt silicide (CoSi₂) contact 18 forms atop the source and drain regions 7 of the substrate 5. Other examples of silicide that are suitable for the metal silicide contact 18 include, but are not limited to: MoSi₂, PtSi₂, TaSi₂, and WSi.

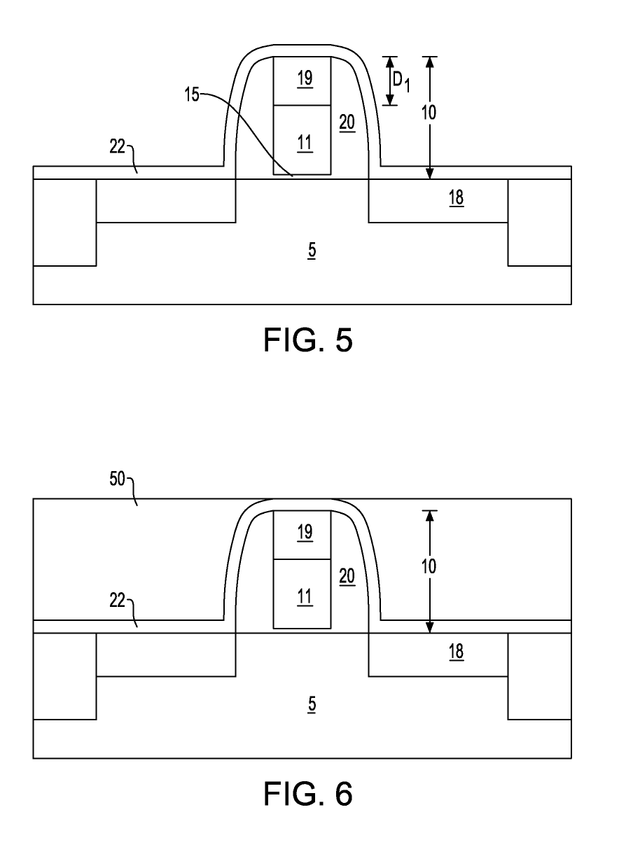

Referring to FIG. 4, in a following process step, in one embodiment an etch process removes un-reacted metals following the alloying of the metal layer 16 with the gate conductor and the source and drain regions 7. In one embodiment, the etch process includes a wet etch that removes the unreacted portions of the metal layer 16 and the metal nitride layer 17 selective to the substrate 5, the facetted spacer 20a, and the silicided gate conductor 11a.

FIGS. 5 to 7 depict another embodiment of the present method for forming a semiconducting device, such as a MOSFET, including a gate structure 10 including a fully silicided gate conductor 11a. In one embodiment, the method begins with a structure similar to the structure depicted in FIG. 1. Differentiated from the embodiment described above with reference to FIGS. 1 to 4, in this embodiment a silicide 19 is formed on the upper portion of the gate conductor 11. In one embodiment, the upper portion of the gate conductor 11 that is consumed by the silicide may range from about 20 nm to about 70 nm, as measured from the original uppermost surface of the gate conductor, wherein the gate conductor has a height ranging from about 70 nm to about 150 nm. In another embodiment, the upper portion of the gate conductor 11 that is consumed by the silicide may extend from the upper surface and extend to ⅓ to ½ of the height of the gate conductor 11. Silicide formation typically requires depositing a refractory metal such as Ni or Ti onto the surface of a Si-containing material. Following deposition, the structure is then subjected to an annealing step including, but not limited to, rapid thermal annealing. During thermal annealing, the deposited metal reacts with Si forming a silicide.

The metal may be deposited atop the silicon containing gate conductor 11 by physical vapor deposition, such as plating or sputtering. In another embodiment, the metal may be deposited by chemical vapor deposition. In one embodiment, the metal deposited atop the silicon containing gate conductor 11 is selected from the group including, but not limited to: Ni, Ti, Co, Mo, Pt, Ta, or W. In one embodiment, the metal that is deposited atop the silicon containing gate conductor 11 has a thickness ranging from about 100 nm to about 200 nm. In another embodiment, the metal that is deposited atop the silicon containing gate conductor 11 has a thickness ranging from about 70 nm to about 150 nm.

In one embodiment, following deposition of the metal, the structure is annealed to react the metal with the silicon containing gate conductor to provide a silicide 19 in the upper portion of the silicon containing gate conductor 11, wherein the structure is annealed at a temperature ranging from about 300° C. to about 600° C., for a time period ranging from about 1 sec to about 30 sec. In another embodiment, the structure is annealed at a temperature ranging from about 350° C. to about 550° C., for a time period ranging from about 1 sec to about 10 sec.

In one embodiment, the upper portion of the silicon containing gate conductor 11 that is consumed during silicidation extends to a depth D1 that is about half the thickness or less of the silicon containing gate conductor 11. In one embodiment, the depth D1 ranges from 20 nm to about 70 nm. In one embodiment, the silicide 19 that is formed on the upper portion of the silicon containing gate conductor is composed of NiSi₂, TiSi₂, CoSi₂, MoSi₂, PtSi₂, TaSi₂, WSi, or combinations thereof.

In one embodiment, in which the metal is also deposited atop the source and drain regions 7 of the substrate 5, during the formation of the silicide 19 on the upper portion of the silicon containing gate conductor 11, silicide contacts 18 are formed on an upper surface of the source and drain regions 7 of the substrate 5. In one embodiment when the metal is composed of Ni and the substrate 5 contains Si, a nickel silicide (NiSi) contact 18 forms atop the source and drain regions 7 of the substrate 5. In another embodiment when the metal is composed of Co and the substrate 5 contains Si, a cobalt silicide (NiSi) contact 18 forms atop the source and drain regions 7 of the substrate 5. In a following process step, in one embodiment an etch process removes un-reacted metals following the alloying of the metal with the gate conductor 11 and the source and drain regions 7.

Still referring to FIG. 5, following the formation of the silicide 19 on the upper portion of the silicon containing gate conductor 11, a first dielectric layer 22 is formed on at least the silicide 19 on the upper portion of the silicon containing gate conductor 11. In one embodiment, the layer of the first dielectric material 22 is blanket deposited atop the gate structure 10 and the upper surface of the substrate 5 adjacent the gate structure 10. In one embodiment, the layer of the first dielectric material 22 is composed of a nitride, oxide, or oxynitride. In one embodiment, the first dielectric layer 22 is composed of silicon nitride.

In one embodiment, the first dielectric layer 22 is deposited by chemical vapor deposition (CVD). Variations of CVD processes include, but are not limited to: Atmospheric Pressure CVD (APCVD), Low Pressure CVD (LPCVD), Plasma Enhanced CVD (EPCVD), Metal-Organic CVD (MOCVD) and combinations thereof. In one embodiment, the first dielectric layer 22 may be deposited using a conformal deposition method. The term “conformal” denotes a layer having a thickness that does not deviate from greater than or less than 20% of an average value for the thickness of the layer. In one embodiment, the thickness of the first dielectric layer 22 ranges from about 2 nm to about 20 nm. In another embodiment, the first dielectric layer 22 has a thickness that ranges from about 5 nm to about 15 nm.

FIG. 6 depicts one embodiment forming second dielectric regions 50 adjacent the gate structure 10, in which an upper surface of the second dielectric regions 50 is coplanar with an upper surface of the first dielectric layer 22 on the metal silicide 19 that is positioned on an upper portion of the silicon containing gate conductor 11. In one embodiment, forming the second dielectric regions 50 includes forming a layer of the second dielectric overlying at least the portions of the substrate adjacent to the gate structure 10, wherein an upper surface of the layer of the second dielectric is planarized to be substantially co-planar with an upper surface of the portion of the first dielectric layer 22 that is positioned atop the metal silicide 19. In one embodiment, the second dielectric region may be composed of an oxide, nitride, oxynitride or combination thereof. In one embodiment, the second dielectric is an oxide that is deposited by chemical vapor deposition. In one embodiment, the second dielectric may be composed of high density plasma (HDP) chemical vapor deposition (CVD) deposited silicon oxide having a thickness ranging from about 10 nm to about 300 nm. HDPCVD is a chemical vapor deposition process that utilizes a low pressure (2-10-mTorr range) to achieve a high electron density (10¹⁰ cm³-10¹² cm³) and a high fractional ionization rate (10⁻⁴ to 10⁻¹) for deposition.

In one embodiment, the layer of the second dielectric extends atop the layer of the first dielectric layer 22 that is positioned atop the gate structure 10. In one embodiment, following deposition, the second dielectric may be planarized to expose the upper surface of the first dielectric layer 22 that is positioned atop the metal silicide 19 of the gate conductor 11. Planarization is a material removal process that employs at least mechanical forces, such as frictional media, to produce a planar surface. In one embodiment, the layer of the second dielectric may be planarized by chemical mechanical polishing (CMP). Chemical Mechanical Planarization is a material removal process using both chemical reactions and mechanical forces to remove material and planarize a surface.

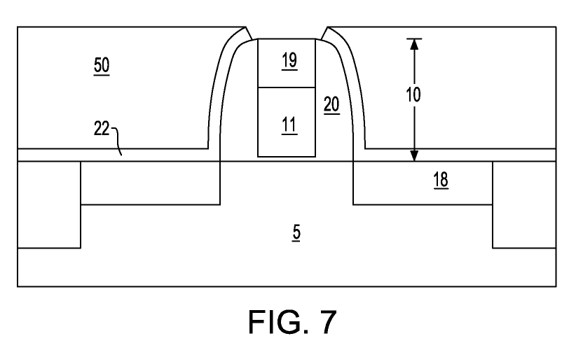

FIG. 7 depicts one embodiment of removing the first dielectric layer 22 from the silicide 19 that is positioned in the upper portion of the gate conductor 11, and directing chemically inert ions to impact the metal silicide 19 at the upper portion of the silicon containing gate conductor 11, wherein momentum transfer from the chemically inert ions forces metal atoms from the metal silicide 19 to a lower portion of the silicon containing gate conductor to provide a fully silicided gate conductor 11a.

In one embodiment, removing the first dielectric layer 22 includes a selective etch process that exposes the metal silicide 19. In one embodiment when the first dielectric layer 22 is composed of a nitride, such as silicon nitride, and the second dielectric regions 50 are composed of an oxide, such as silicon oxide, the exposed portion of the first dielectric layer 22 is removed from the metal silicide 19 by a selective etch process, in which the etch chemistry removes the nitride first dielectric layer 22 at a faster rate than the oxide second dielectric regions 50. In one embodiment, the etch chemistry removes the nitride first dielectric layer 22 selective to the metal silicide 19. In another embodiment, a block mask is formed protecting the second dielectric regions 50, while an etch process removes the exposed portion of the first dielectric layer 22, wherein the block mask may comprise soft and/or hardmask materials and can be formed using deposition, photolithography and etching.

In a following process step, chemically inert ions impact the exposed surface of the metal silicide 19 at the upper portion of the silicon containing gate conductor 11, wherein momentum transfer of the chemically inert ions forces metal atoms from the metal silicide 19 into a lower portion of the silicon containing gate conductor to provide a fully silicided gate conductor. In one embodiment, the chemically inert ions include Ar+ or N+ or Kr+.

In one embodiment, the directing chemically inert ions is provided by ion milling, which may also be referred to as sputtering. In one embodiment, ion milling includes positioning the substrate 5 containing the gate structure 10 in a vacuum chamber, wherein a stream of argon is introduced into the chamber. Upon entering the chamber, the argon is subjected to a stream of high-energy electrons from a set of anode and cathode electrodes. The electrons ionize the argon atoms to a high-energy state with a positive charge. The substrate 5 is held on a negatively grounded holder, which attracts the ionized argon atoms. As the argon atoms travel to the gate structure 10 they accelerate picking up momentum.

In one embodiment, the chemically inert ions have an ion energy ranging from about 5 eV to about 200 eV. In another embodiment, the chemically inert ions have an ion energy ranging from about 10 eV to about 100 eV. In an even further embodiment, the chemically inert ions have an ion energy ranging from about 20 eV to about 70 eV.

In one embodiment, the directing of the chemically inert ions includes ion milling at a temperature ranging from about 300° C. to about 600° C. In another embodiment, the directing of the chemically inert ions includes ion milling at a temperature ranging from about 350° C. to about 600° C. In an even further embodiment, the directing of the chemically inert ions includes ion milling at a temperature ranging from about 350° C. to about 550° C.

In one embodiment, directing the chemically inert atoms to contact the metal silicide 19 force metal atoms from the metal silicide to a lower portion of the silicon containing gate conductor to provide a fully silicided gate conductor. In one embodiment, this can accelerate to form fully silicided gate.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed as new is:

1. A method of producing a device comprising:
providing a semiconducting device comprising a gate structure including a silicon containing gate conductor atop a substrate;
forming a metal layer on at least the silicon containing gate conductor; and
directing chemically inert ions to impact the metal layer, wherein the chemically inert ions force metal atoms from the metal layer into the silicon containing gate conductor to provide a metal silicide gate conductor.

2. The method of claim 1, further comprising forming a metal nitride layer atop the metal layer prior to the step of directing the chemically inert ions to impact the metal layer.

3. The method of claim 1, wherein the chemically inert ions include Ar+, N+, Kr+, Xe+ or combinations thereof.

4. The method of claim 1, wherein the chemically inert ions have an ion energy ranging from about 5 eV to about 200 eV.

5. The method of claim 1, wherein the directing of the chemically inert ions includes sputtering.

6. The method of claim 5, wherein the sputtering further comprises a temperature ranging from about 400° C. to about 600° C., the chemically inert ions comprise Ar, N, or combinations thereof, and the chemically inert ions are directed to impact the metal layer with a ion energy ranging from about 5 eV to about 200 eV.

7. The method of claim 5, wherein the silicide gate conductor is a fully silicided gate conductor.

8. The method of claim 5, wherein the metal is comprised of Ni, Co, Ti, Pt, Ta, W or combinations thereof.

9. The method of claim 2, wherein the metal nitride is comprised of TiN, TaN, WN, or combinations thereof.

10. A method of producing a device comprising:
providing a semiconducting device comprising a gate structure including a silicon containing gate conductor atop a substrate;
forming a silicide on at least an upper portion of the silicon containing gate conductor; and
directing chemically inert ions to impact the silicide at the upper portion of the silicon containing gate, wherein the chemically inert ions force metal atoms from the silicide to a lower portion of the silicon containing gate conductor to provide a fully silicided gate conductor.

11. The method of claim 10, wherein prior to the directing of the chemically inert ions to impact the silicide the method further comprises:
forming a first dielectric layer on at least the silicide on the upper portion of the silicon containing gate conductor;
forming second dielectric regions adjacent the gate structure, wherein an upper surface of the second dielectric regions is coplanar with an upper surface of the first dielectric layer on the silicide that is positioned in an upper portion of the silicon containing gate conductor; and
removing the first dielectric layer from the silicide.

12. The method of claim 10, wherein the step of forming the first dielectric layer on at least the silicide comprises depositing a nitride.

13. The method of claim 10, wherein the step of forming the second dielectric regions comprises depositing an oxide atop the substrate and the gate structure; and
planarizing the oxide until the upper surface of the first dielectric layer is exposed.

14. The method of claim 10, wherein the step of removing the first dielectric layer includes an anisotropic etch step including an etch chemistry for removing the first dielectric layer selective to the second dielectric regions.

15. The method of claim 10, wherein the silicide comprises NiSi₂, TiSi₂, CoSi₂, MoSi₂, PtSi₂, TaSi₂, WSi, or combinations thereof.

16. The method of claim 10, wherein the chemically inert ions include Ar+, N+, Kr+, Xe+ or combinations thereof.

17. The method of claim 10, wherein the chemically inert ions have an ion energy ranging from about 5 eV to about 200 eV.

18. The method of claim 10, wherein the directing of the chemically inert ions includes sputtering.

19. A semiconducting device:
a substrate including a channel positioned between a source and a drain region; and
a gate structure including a gate stack and a facetted spacer abutting the gate stack, the gate structure comprised of a gate dielectric positioned atop the channel of the substrate, and a fully silicided gate conductor atop the gate dielectric, wherein an angle at an intersection of a planar upper face of the facetted spacer and a sidewall of the facetted spacer abutting the gate conductor is less than about 75 degrees.

20. The device of claim 19, wherein said gate stack is facetted on the top of the gate.
